(19) United States
(12) Patent Application Publication
(10) Pub. No.: US 2026/0334279 A1
(43) Pub. Date: Oct. 22, 2026

(54) SEMICONDUCTOR DEVICE

(71) Applicant: FUJI ELECTRIC CO., LTD., Kawasaki-shi (JP)

(72) Inventors: Fumihiko MOMOSE, Kawasaki-shi (JP); Tsunehiro NAKAJIMA, Kawasaki-shi (JP); Ryoto UCHIYAMA, Kawasaki-shi (JP); Takafumi UCHIDA, Kawasaki-shi (JP)

(73) Assignee: FUJI ELECTRIC CO., LTD., Kawasaki-shi (JP)

(21) Appl. No.: 19/692,191

(22) Filed: May 29, 2026

Related U.S. Application Data
(63) Continuation of application No. PCT/JP2025/016874, filed on May 8, 2025.

(30) Foreign Application Priority Data
Jun. 6, 2024 (JP) 2024-091877

(51) Int. Cl. H10W 72/50

(52) U.S. Cl. CPC H10W 72/5438; H10W 72/527; H10W 72/531

(57) ABSTRACT

A semiconductor device, including: a semiconductor element having an electrode exposed on a surface thereof; and a plurality of wires bonded to the electrode, thereby forming a plurality of bonding areas thereof. Each of the plurality of wires is of a first wire diameter. A ratio of a total area of the plurality of bonding areas to an area of the electrode is at least 0.123.

### CROSS-REFERENCE TO RELATED APPLICATIONS

This is a continuation application of International Application PCT/JP2025/016874 filed on May 8, 2025 which claims priority from a Japanese Patent Application No. 2024-091877 filed on Jun. 6, 2024, the contents of which are incorporated herein by reference.

### TECHNICAL FIELD

The present invention relates to a semiconductor device.

### BACKGROUND ART

As a semiconductor device used for a power conversion device, there is a semiconductor device in which an electrode of a semiconductor element such as an Insulated Gate Bipolar Transistor (IGBT) and a conductor pattern such as a wiring board are connected by a wire (for example, Patent Literature 1 and 2).

### CITATION LIST

### Patent Literature

Patent Literature 1: JP 2005-166854 A

Patent Literature 2: JP 2008-186957 A

### SUMMARY OF INVENTION

### Technical Problem

The above-described semiconductor device is required to have a high surge energy capability in order to prevent destruction of the semiconductor element due to a high current that is suddenly generated.

One object of the present invention is to increase a surge energy capability of a semiconductor device.

### Solution to Problem

A semiconductor device according to one aspect includes a semiconductor element and a plurality of wires bonded to an electrode exposed on a surface of the semiconductor element. The plurality of wires include a wire having a first wire diameter, and a sum of bonding areas of the electrode and the plurality of wires is 0.123 mm² or more per 1 mm² of the electrode of the semiconductor element.

### Advantageous Effects of Invention

According to the above aspect, it is possible to increase a surge energy capability of a semiconductor device.

### BRIEF DESCRIPTION OF DRAWINGS

FIG. 1 is a plan view of a semiconductor device according to an embodiment.

FIG. 2 is a cross-sectional view for illustrating a configuration example of the inside of a case for the semiconductor device in FIG. 1.

FIG. 3 is a circuit diagram of an inverter circuit formed in the semiconductor device in FIG. 1.

FIGS. 4A and 4B are plan views illustrating a relationship between a wire diameter of a wire and a bonding point.

FIGS. 5A and 5B are side views illustrating the relationship between the wire diameter of the wire and the bonding point.

FIG. 6 is a table illustrating a relationship between the number of bonding points and the bonding area for each wire diameter of the wire.

FIG. 7 is a graph illustrating a relationship between the number of wires and the surge energy capability for each wire diameter.

FIG. 8 is a graph illustrating a relationship between the number of bonding points and the surge energy capability for each wire diameter.

FIG. 9 is a graph illustrating a relationship between the bonding area and the surge energy capability for each wire diameter.

FIG. 10 is a graph illustrating a relationship between the number of wires per unit area and the surge energy capability for each wire diameter.

FIG. 11 is a graph illustrating a relationship between the number of bonding points per unit area and the surge energy capability for each wire diameter.

FIG. 12 is a graph illustrating a relationship between the bonding area per unit area and the surge energy capability for each wire diameter.

### DESCRIPTION OF EMBODIMENTS

Hereinafter, embodiments of the present invention will be described in detail with reference to the drawings. An X axis, a Y axis, and a Z axis in each of the drawings to be referred to are illustrated for the purpose of defining a plane and a direction in the illustrated semiconductor device. The X axis, the Y axis, and the Z axis are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is attached.

In the present specification, the Z direction may be referred to as an up-down direction. In the present specification, “on” and “upper” are intended to be on the positive side in the Z direction with respect to the reference surface, member, position, and the like, and “under” and “lower” are intended to be on the negative side in the Z direction with respect to the reference surface, member, position, and the like. For example, when the expression “a member B is disposed on a member A” is described, the member B is disposed on the positive side in the Z direction as viewed from the member A. Also, when the expression “the upper surface of the member A” is described, the surface includes a surface that is positioned at the end of the member A on the positive side in the Z direction and faces the positive side in the Z direction. These directions and surfaces associated with the directions are words to be used for convenience of description, and a correspondence relationship with the directions of the X axis, the Y axis, and the Z axis may change depending on the mounting orientation of the semiconductor device and the like. For example, in the present specification, a surface of a semiconductor element facing a wiring board is referred to as a lower surface, and a surface opposite to the lower surface is referred to as an upper surface, but the present invention is not limited thereto, and a surface facing the wiring board may be referred to as an upper surface, and a surface opposite thereto may be referred to as a lower surface.

An aspect ratio and a magnitude relationship between the members in each drawing are merely schematically represented, and do not necessarily coincide with a relationship in the semiconductor device actually manufactured. For convenience of description, it is also assumed that a magnitude relationship between the members is exaggeratedly expressed, or an expression is different from an outer shape of a member used in the actual semiconductor device. Also, for convenience of description, some of the cross-sectional views illustrate a cross-sectional configuration of the semiconductor device cut along a virtual cutting line that is not able to be accurately illustrated in the plan view.

The expressions of “not illustrated” and the like in the present specification mean that components to which the expressions are given or the reference signs and lead lines clearly indicating the components are not illustrated in the figures. For example, a “first main electrode not illustrated” is intended to mean both that a portion representing the first main electrode (for example, a shape, a line, or the like) is not illustrated in the figure, and that neither a reference sign nor a lead line clearly indicating a portion corresponding to the first main electrode is illustrated in the figure. Also, the underlined reference sign in the figure indicates the entirety of components including a plurality of portions distinguished by a plurality of reference signs.

A semiconductor device to be illustrated in the following description may be applied to, for example, a power conversion device such as an industrial or electrical (for example, an in-vehicle motor's) inverter device. Therefore, in the following description, detailed description of the same or similar configuration, function, operation, manufacturing method, and the like as those of the known semiconductor device will be omitted. The “semiconductor device” in the present specification is obtained by sealing a semiconductor element that may be referred to as a semiconductor chip, a die, or the like with an insulating material, and may be referred to as a “semiconductor module” or the like. In addition, a “surge energy capability” in the present invention may be a value represented by a product of a surge current capability IFSM and a voltage VFSM. The surge current capability IFSM is a maximum value of a non-repetitive forward surge current in a sine wave half cycle (pulse width tp=10 ms) of a commercial frequency, and the voltage VFSM is a value of a forward voltage Vf of a diode element at the time of measuring the surge current capability IFSM.

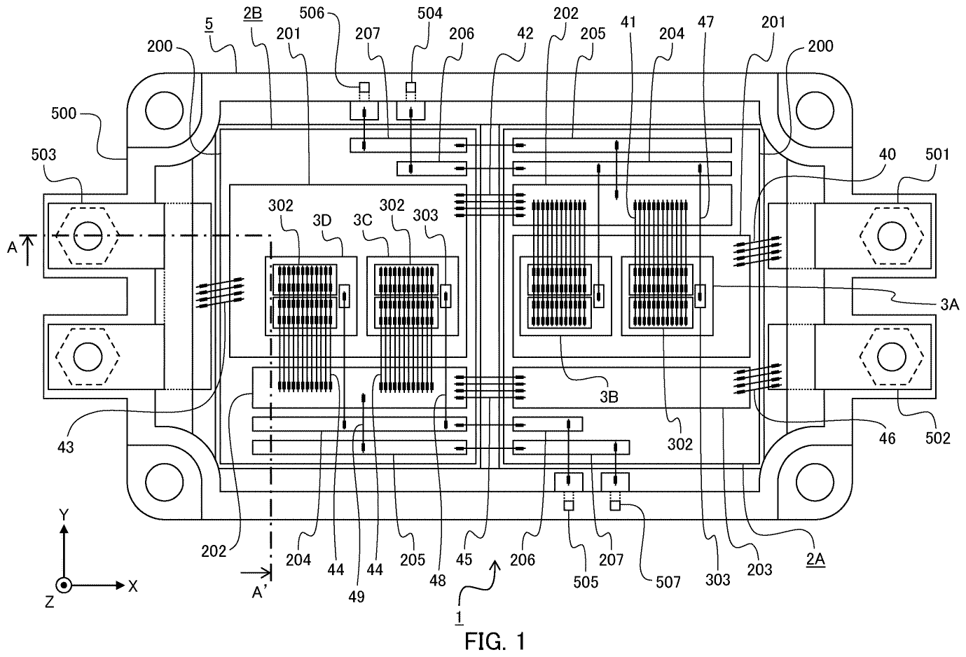

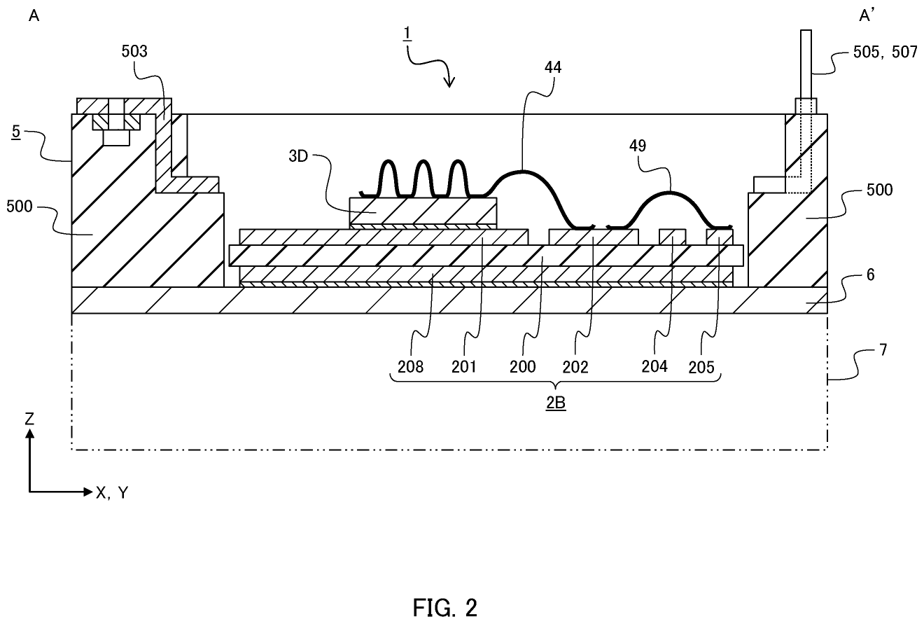

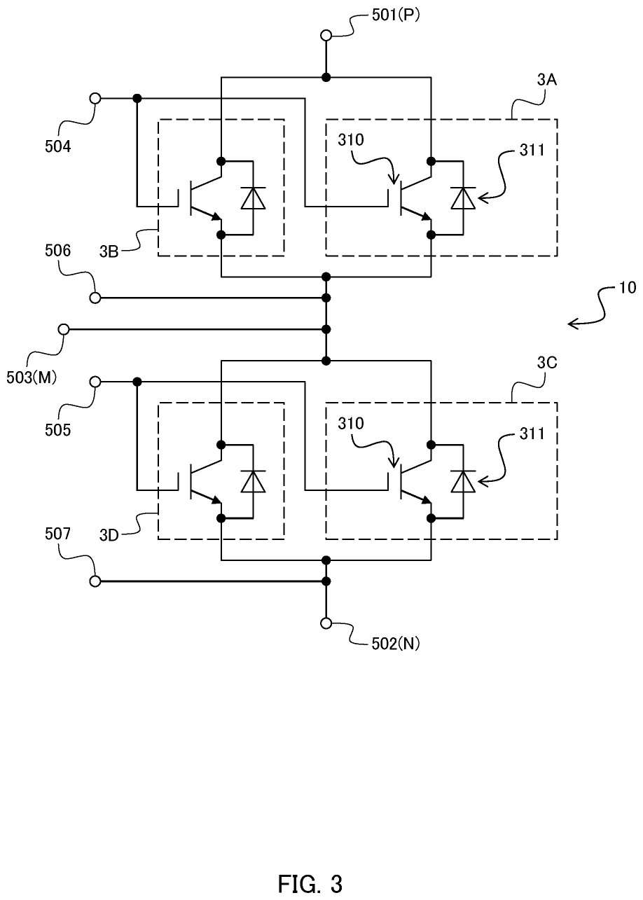

FIG. 1 is a plan view of a semiconductor device according to an embodiment. FIG. 2 is a cross-sectional view for illustrating a configuration example of the inside of a case for the semiconductor device in FIG. 1. FIG. 3 is a circuit diagram of an inverter circuit formed in the semiconductor device in FIG. 1. The cross-sectional view of FIG. 2 may be an example of a cross-sectional configuration when the semiconductor device 1 in FIG. 1 is cut along one-dot chain line A-A′.

The semiconductor device 1 according to the present embodiment includes wiring boards 2A and 2B, semiconductor elements 3A to 3D, wires 40 to 49, a case 5, a sealing material (not illustrated), and a heat dissipation plate 6. In the present specification, when referring to components referred to by signs each represented by a combination of a number and an alphabet following the number, the number and the alphabet are described in a case where components to which the same numbers are assigned are distinguished from each other, and only the number is described in a case where the components are not distinguished from each other. For example, in a case where a specific semiconductor element among the plurality of semiconductor elements 3A to 3D is designated, the reference sign assigned to the specific semiconductor element in FIG. 1 is described (for example, “semiconductor element 3A” is described), and in other cases, the semiconductor element is simply described as “semiconductor element 3”. In addition, when referring to a plurality of components having the same name, modifiers “first” and “second” may be added. For example, wiring board 2A and wiring board 2B may be referred to as “first wiring board 2A” and “second wiring board 2B”, respectively. It should be noted that the modifiers “first” and “second” are used only for the purpose of distinguishing a plurality of identical components, and are not intended to identify the order of those components.

The wiring board 2 is an element-mounted component on which the semiconductor element 3, which is sometimes referred to as a semiconductor chip, a die, or the like, is mounted. The semiconductor element 3 may be, for example, a Reverse Conducting (RC)-IGBT element in which a function of a switching element such as an Insulated Gate Bipolar Transistor (IGBT) element and a function of a diode element such as a Free Wheeling Diode (FWD) element are integrated. The wiring board 2 and the semiconductor element 3 are circuit components for forming a half-bridge inverter circuit 10 illustrated in FIG. 3.

The first wiring board 2A includes an insulating substrate 200, conductor patterns 201 to 207 disposed on the upper surface of the insulating substrate 200, and a heat dissipation pattern disposed on the lower surface of the insulating substrate 200. The second wiring board 2B includes an insulating substrate 200, conductor patterns 201, 202, and 204 to 207 disposed on the upper surface of the insulating substrate 200, and a heat dissipation pattern 208 disposed on the lower surface of the insulating substrate 200. The wiring board 2 may be a Direct Copper Bonding (DCB) substrate or an Active Metal Brazing (AMB) substrate, but is not limited thereto. The first wiring board 2A and the second wiring board 2B may be integrated.

The insulating substrate 200 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 200 may be a substrate obtained by molding an insulating resin such as epoxy resin into a sheet shape, a substrate obtained by impregnating a base material such as a glass fiber with an insulating resin, a substrate obtained by coating a surface of a flat plate-shaped metal core with an insulating resin, or the like.

The conductor patterns 201 to 207 disposed on the upper surface of the insulating substrate 200 are used as wiring in an electronic circuit such as an inverter circuit formed in the semiconductor device 1. The heat dissipation pattern 208 disposed on the lower surface of the insulating substrate 200 is used as a heat dissipation component that conducts heat generated by the semiconductor element 3 during operation of the semiconductor device 1 to the heat dissipation plate 6. These conductor patterns 201 to 207 and the heat dissipation pattern 208 are made of, for example, metal foils such as copper or aluminum.

The wiring board 2 is disposed on the upper surface of the heat dissipation plate 6. The heat dissipation pattern 208 of the wiring board 2 is connected to be in close contact with the upper surface of the heat dissipation plate 6 by using a bonding material such as not illustrated solder or a thermally conductive material such as thermal grease or a thermal compound. The heat dissipation plate 6 may be, for example, a metal plate made of copper or aluminum. A plurality of fins may be provided on the lower surface of the heat dissipation plate 6. The heat dissipation plate 6 may be a portion of a cooler 7 or a component connected to the cooler 7. That is, the cooler 7 is an optional component in the semiconductor device 1 of the present embodiment. The cooler 7 is not limited to one having a particular cooling scheme and a particular structure.

In the semiconductor device 1 illustrated in FIGS. 1 and 2, the case 5 is disposed on the upper surface of the heat dissipation plate 6. The case 5 includes a frame-shaped insulating member 500 having open ends on the upper surface and the lower surface thereof, and a plurality of terminals 501 to 507 integrated with the insulating member 500. The insulating member 500 of the case 5 may have a shape in which, when being disposed on the upper surface of the heat dissipation plate 6, a space is defined that houses the wiring board 2, the semiconductor element 3, the wires 40 to 49, and the like, and that may be filled with a sealing material for sealing them. The open end on the upper surface side of the insulating member 500 may be covered with, for example, a lid (not illustrated) made of an insulating material.

The terminals 501 to 507 of the case 5 are roughly divided into main terminals 501 to 503 and control terminals 504 to 507. The main terminals 501 to 503 are connected to an electrode that causes a main current to flow through a switching element such as an IGBT element in the semiconductor element 3. In the case of the semiconductor device 1 in which the half-bridge inverter circuit 10 illustrated in FIG. 3 is formed, the first main terminal 501 can be a P terminal connected to the positive electrode of a DC power supply, and is connected to the collector electrodes of IGBT elements 310 in the semiconductor elements 3A and 3B disposed on the upper surface of the first wiring board 2A. The second main terminal 502 can be an N terminal connected to the negative electrode of the DC power supply, and is connected to the emitter electrodes of the IGBT elements 310 in the semiconductor elements 3C and 3D disposed on the upper surface of the second wiring board 2B. The third main terminal 503 is a middle terminal (M terminal) connected to a load, and is connected to the emitter electrodes of the IGBT elements 310 in the semiconductor elements 3A and 3B disposed on the upper surface of the first wiring board 2A and the collector electrodes of the IGBT elements 310 in the semiconductor elements 3C and 3D disposed on the upper surface of the second wiring board 2B. The above-described semiconductor element 3, which is an RC-IGBT element, includes the IGBT element 310 and a diode element 311 connected in anti-parallel to the IGBT element 310. The semiconductor element 3 in the semiconductor device 1 illustrated in FIGS. 1 and 2 is disposed on the wiring board 2 in a direction in which the collector electrode is disposed on the lower surface thereof and an emitter electrode 302 and a gate electrode 303 are disposed on the upper surface thereof.

The collector electrodes of the semiconductor elements 3A and 3B on the first wiring board 2A are bonded to the first conductor pattern 201 of the wiring board 2 by a bonding material such as solder. The first conductor pattern 201 of the first wiring board 2A is electrically connected to the first main terminal 501 by the wire 40. The emitter electrodes 302 of the semiconductor elements 3A and 3B on the first wiring board 2A are electrically connected to the second conductor pattern 202 of the first wiring board 2A by the wire 41. The second conductor pattern 202 of the first wiring board 2A is electrically connected to the first conductor pattern 201 of the second wiring board 2B by the wire 42. The first conductor pattern 201 of the second wiring board 2B is bonded to the collector electrodes of the semiconductor elements 3C and 3D, and is electrically connected to the third main terminal 503 by the wire 43. The emitter electrodes 302 of the semiconductor elements 3C and 3D are electrically connected to the second conductor pattern 202 of the second wiring board 2B by the wire 44. The second conductor pattern 202 of the second wiring board 2B is electrically connected to the third conductor pattern 203 of the first wiring board 2A by the wire 45, and the third conductor pattern 203 of the first wiring board 2A is electrically connected to the second main terminal 502 by the wire 46.

The gate electrodes 303 of the semiconductor elements 3A and 3B are electrically connected to the fourth conductor pattern 204 of the first wiring board 2A by the wire 47. The fourth conductor pattern 204 of the first wiring board 2A is electrically connected to the first control terminal 504 via the wire and the sixth conductor pattern 206 of the second wiring board 2B. The gate electrodes 303 of the semiconductor elements 3C and 3D are electrically connected to the fourth conductor pattern 204 of the second wiring board 2B by the wire 48. The fourth conductor pattern 204 of the second wiring board 2B is electrically connected to the second control terminal 505 via the wire and the sixth conductor pattern 206 of the first wiring board 2A.

In addition, the half-bridge inverter circuit 10 illustrated in FIG. 3 includes auxiliary control terminals 506 and 507 each called an auxiliary emitter terminal, a sense emitter terminal, an emitter sense terminal, or the like. The first auxiliary control terminal 506 is electrically connected to the emitter electrodes 302 of the semiconductor elements 3A and 3B, and is connected to a control circuit (not illustrated) that generates a control signal to be applied to the gate electrodes 303 of the semiconductor elements 3A and 3B. The second auxiliary control terminal 507 is electrically connected to the emitter electrodes 302 of the semiconductor elements 3C and 3D, and is connected to a control circuit (not illustrated) that generates a control signal to be applied to the gate electrodes 303 of the semiconductor elements 3C and 3D. In the case of the semiconductor device 1 having the auxiliary emitter terminal, the second conductor pattern 202 of the first wiring board 2A is electrically connected to the first auxiliary control terminal 506 via the wire, the fifth conductor pattern 205 of the first wiring board 2A, the seventh conductor pattern 207 of the second wiring board 2B, and the like. Similarly, the second conductor pattern 202 of the second wiring board 2B is electrically connected to the second auxiliary control terminal 507 via the wire 49, the fifth conductor pattern 205 of the second wiring board 2B, the seventh conductor pattern 207 of the first wiring board 2A, and the like.

Note that the semiconductor device 1 and the half-bridge inverter circuit 10 described above with reference to FIGS. 1 to 3 are merely examples of the semiconductor devices to which the present invention can be applied. The wiring board 2, the semiconductor element 3, the case 5, and the like in the semiconductor device 1 are not limited to those having a specific configuration. The electronic circuit formed in the semiconductor device 1 to which the present invention can be applied is not limited to the half-bridge inverter circuit 10 described above.

In the semiconductor device 1 of the present embodiment, the emitter electrode 302 in each semiconductor element 3 is electrically connected to the conductor pattern 202 of the wiring board 2 by the plurality of wires 41 or 44. By making such a connection, a bonding area of the emitter electrode 302 to the wires 41 or 44 can be increased, and the surge energy capability of the semiconductor element 3 can be increased. However, the bonding area between the emitter electrode 302 of the semiconductor element 3 and the wires 41 or 44 has restrictions in accordance with the combination of the dimension of the region, on the upper surface of the semiconductor element 3, in which the emitter electrode 302 is exposed and the wire diameter of the wires 41 or 44. Note that the wires 41 and 44 may be made of aluminum, an aluminum alloy, or the like, but are not limited to those made of a specific material. In the present specification, the wires 41 and 44 bonded to the emitter electrode 302 of the semiconductor element 3 will be described as wires having a circular cross section, but the cross-sectional shape of the wires 41 and 44 is not limited to a circular shape.

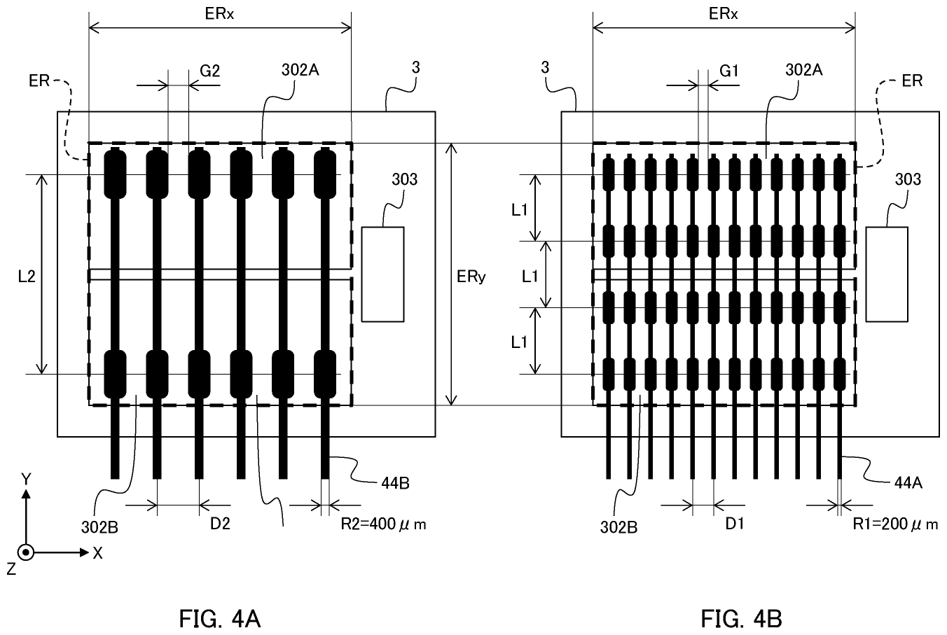

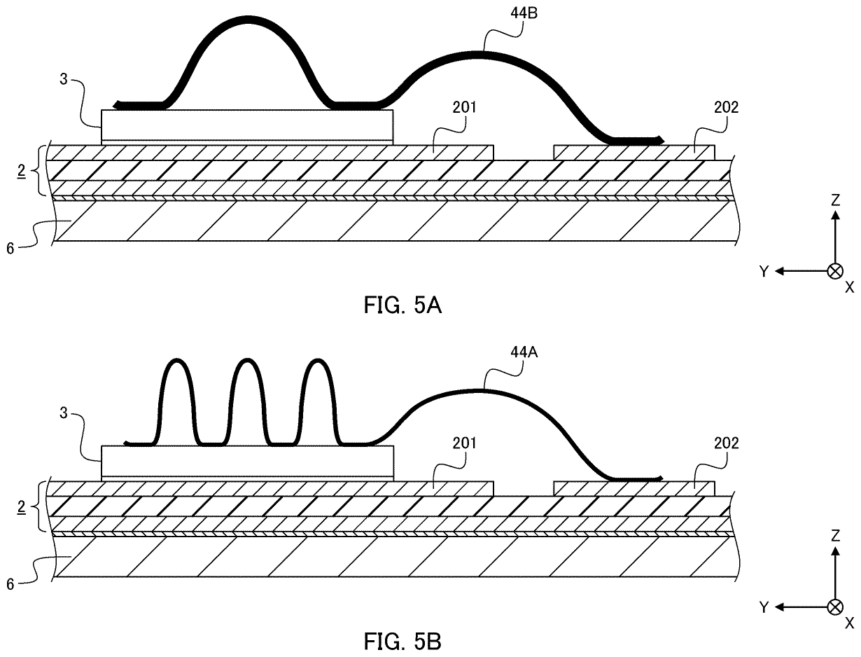

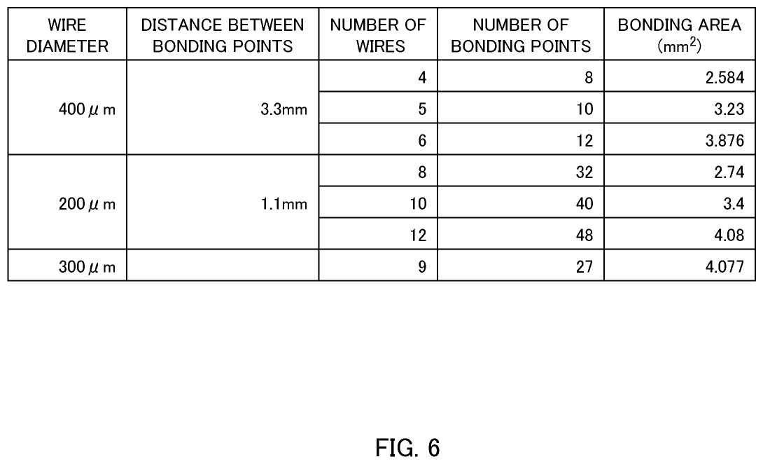

FIGS. 4A and 4B are plan views illustrating a relationship between the wire diameter of the wire and the bonding point. FIGS. 5A and 5B are side views illustrating a relationship between the wire diameter of the wire and the bonding point. FIG. 6 is a table illustrating a relationship between the number of bonding points and the bonding area for each wire diameter of the wire. The side view in FIG. 5A may be the left side view of FIG. 4A, and the side view in FIG. 5B may be the left side view of FIG. 4B. Although the emitter electrode 302 of the semiconductor element 3 illustrated in FIGS. 4A and 4B is divided into two in the extending direction (Y direction) of the wire 44, the emitter electrode 302 may be a single electrode that is not divided, or may be divided in another division pattern.

FIGS. 4A and 5A illustrate an example of a distance D2 between the wires and the number of bonding points to the emitter electrode 302 in a case where the emitter electrode 302 of the semiconductor element 3 and the conductor pattern 202 of the wiring board 2 are connected by a wire 44B having a wire diameter R2 of 400 μm (hereinafter referred to as a “wire 44B having a second wire diameter”). In the wire bonding using the wire 44B having the second wire diameter, a distance L2 between the bonding points when two portions of one wire 44B are bonded to the conductor such that a loop is formed therebetween can be, for example, about 3.3 mm. Therefore, for example, in a case where a dimension ERy in the extending direction (Y direction) of the wire 44B in a region ER, on the upper surface of the semiconductor element 3, in which the emitter electrode 302 is exposed is about 5.0 mm, the number of bonding points of each wire 44B having the second wire diameter to the emitter electrode 302 is two. Therefore, when the emitter electrode 302 of the semiconductor element 3 whose dimension ERy in the region ER is 5.0 mm is electrically connected to the conductor pattern 202 of the wiring board 2 by the wire 44B having the second wire diameter, the relationship among the number of wires, the number of bonding points, and the bonding area is as illustrated in FIG. 6. The bonding area of the wire 44B having the second wire diameter (R2=400 μm) illustrated in FIG. 6 is derived, setting the bonding area of one bonding point as 0.323 mm², which is the bonding area when bonding is performed using a general bonding tool. In practice, the wire and the electrode are connected to each other by bonding in a predetermined finite area in a planar view. The term “bonding point” in the present specification corresponds to the central portion of the area in which the wire and the electrode are connected to each other by bonding. For example, at a bonding portion between the wire and the electrode having a bonding area close to an elliptical shape, an intersection portion between a major axis and a minor axis of the ellipse is a bonding point. In the present specification, the distance between the bonding points and the like are defined.

In a case where the plurality of wires 44B having the second wire diameter are bonded to the emitter electrode 302 of the semiconductor element 3 in the direction (X direction) orthogonal to the extending direction (Y direction) of the wires, the minimum value (minimum distance D2min) of the distance D2 between the wires in the X direction depends on the dimension of the bonding tool in the X direction (in other words, the dimension is a gap G2 between the bonding points of the adjacent wires 44B illustrated in FIG. 4A). The minimum distance D2min between the wires 44B having the second wire diameter can be 0.8 mm. Therefore, in a case where a dimension ERx in the X direction in the region ER illustrated in FIG. 4A is 5.0 mm, the number of the wires 44B having the second wire diameter that can be used for bonding to the emitter electrode 302 of the semiconductor element 3 is six to seven at the maximum.

FIGS. 4B and 5B illustrate an example of a distance D1 between the wires and the number of bonding points to the emitter electrode 302 in a case where the emitter electrode 302 of the semiconductor element 3 and the conductor pattern 202 of the wiring board 2 are connected by a wire 44A having a wire diameter R1 of 200 μm (hereinafter referred to as a “wire 44A having a first wire diameter”). In the wire bonding using the wire 44A having the first wire diameter, a distance L1 between the bonding points when two portions of one wire 44A are bonded to the conductor such that a loop is formed therebetween can be, for example, about 1.1 mm. Therefore, for example, in a case where a dimension ERy in the extending direction (Y direction) of the wire 44A in the region ER, on the upper surface of the semiconductor element 3, in which the emitter electrode 302 is exposed is about 5.0 mm, the number of bonding points of each wire 44A having the first wire diameter to the emitter electrode 302 is four. The distance L1 can be set to 1.0 mm or 0.9 mm depending on the performance of the bonding tool or the performance of the device. In a case where the plurality of wires 44A having the first wire diameter are bonded to the emitter electrode 302 of the semiconductor element 3 in the direction (X direction) orthogonal to the extending direction (Y direction) of the wires 44A, the minimum value (minimum distance D1min) of the distance D1 between the wires 44A having the first wire diameter that can depend on a gap G1 between the adjacent bonding points in the X direction can be 0.4 mm. Therefore, in a case where a dimension ERx in the X direction in the region ER illustrated in FIG. 4B is 5.0 mm (that is, the dimension ERx is the same as the dimension of the region ER illustrated in FIG. 4A), the number of the wires 44A having the first wire diameter that can be used for bonding to the emitter electrode 302 of the semiconductor element 3 is 12 to 13 at the maximum. Therefore, when the emitter electrode 302 of the semiconductor element 3 whose dimension in the region ER is the above-described dimension is electrically connected to the conductor pattern 202 of the wiring board 2 by the wire 44A having the first wire diameter, the relationship between the number of wires 44A and the bonding area is as illustrated in FIG. 6. The bonding area of the wire 44A having the first wire diameter (R1=200 μm) illustrated in FIG. 6 is derived, setting the bonding area of one bonding point as 0.085 mm², which is the bonding area when bonding is performed using a general bonding tool.

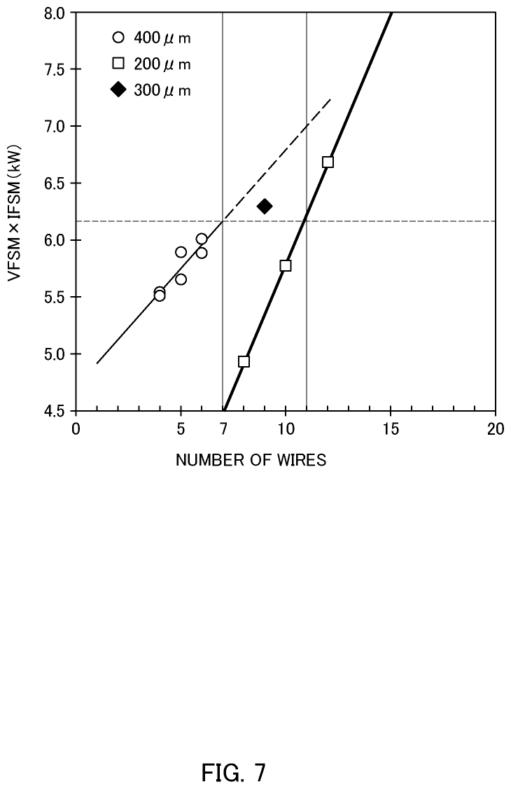

As mentioned above, the minimum distance D1min (=0.4 mm) between the wires 44A having the first wire diameter (200 μm) may be ½ of the minimum distance D2min (=0.8 mm) between the wires 44B having the second wire diameter (400 μm). Therefore, for example, by changing the wire to be bonded to the emitter electrode 302 of the semiconductor element 3 from the wire 44B having a wire diameter of 400 μm to the wire 44A having a wire diameter of 200 μm and doubling the number of wires, the bonding area can be increased. However, as described below with reference to FIGS. 7 to 9, the surge energy capability of the semiconductor element 3 may not be increased simply by selecting a wire having a small wire diameter and increasing the bonding area.

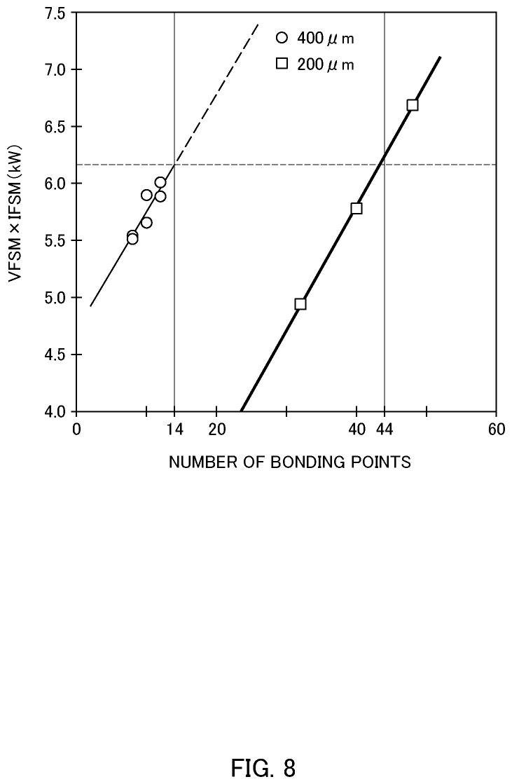

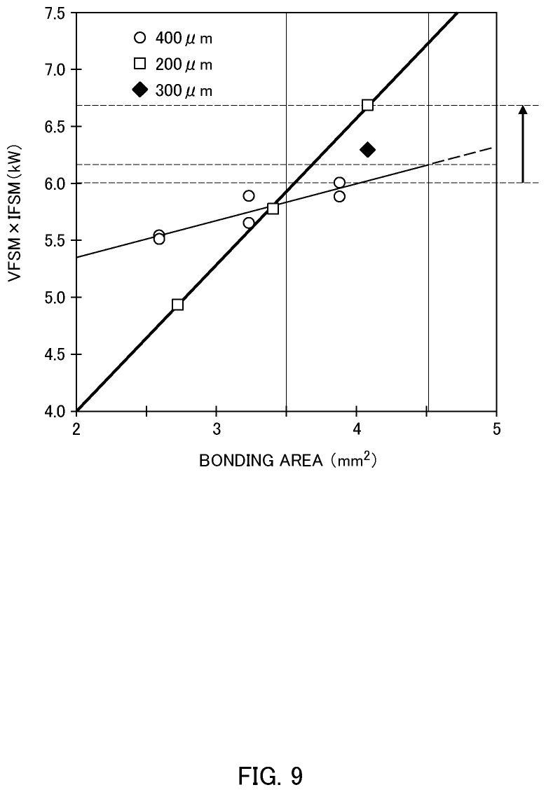

FIG. 7 is a graph illustrating a relationship between the number of wires and the surge energy capability for each wire diameter. FIG. 8 is a graph illustrating a relationship between the number of bonding points and the surge energy capability for each wire diameter. FIG. 9 is a graph illustrating a relationship between the bonding area and the surge energy capability for each wire diameter. The surge energy capability in each of the graphs in FIGS. 7 to 9 is a product of the surge current capability IFSM and the voltage VFSM. As described above, the surge current capability IFSM is a maximum value of a non-repetitive forward surge current in a sine wave half cycle (pulse width tp=10 ms) of a commercial frequency, and the voltage VFSM is a value of a forward voltage Vf of a diode element at the time of measuring the surge current capability IFSM.

As can be seen from the graphs in FIGS. 7 to 9, in a case where the wire 44A having the first wire diameter (200 μm) is bonded to the emitter electrode 302 of the semiconductor element 3, and in a case where the wire 44B having the second wire diameter (400 μm) is bonded to the emitter electrode 302 of the semiconductor element 3, the surge energy capability increases as the number of wires, the number of bonding points, and the bonding area increase.

However, for example, the surge energy capability when the eight wires 44A having the first wire diameter are bonded to the emitter electrode 302 of the semiconductor element 3 is smaller than the surge energy capability when the four wires 44A having the first wire diameter are bonded to the emitter electrode 302 of the semiconductor element 3. The bonding area when the eight wires 44A having the first wire diameter are bonded to the emitter electrode 302 of the semiconductor element 3 is 2.74 mm², which is larger than the bonding area (2.584 mm²) when the four wires 44B having the second wire diameter are bonded to the emitter electrode 302 of the semiconductor element 3. However, in the graph in FIG. 9, the surge energy capability when the bonding area of the wire having a wire diameter of 200 μm is 2.74 mm² is smaller than the surge energy capability when the bonding area of the wire having a wire diameter of 400 μm is 2.584 mm². Although the bonding area to the emitter electrode 302 when ten wires 44A having the first wire diameter are bonded to the emitter electrode 302 of the semiconductor element 3 is larger than that when five wires 44B having the second wire diameter are bonded to the emitter electrode 302 of the semiconductor element 3, the surge energy capabilities can be substantially the same. On the other hand, when 12 wires 44A having the first wire diameter are bonded to the emitter electrode 302 of the semiconductor element 3, the bonding area to the emitter electrode 302 is 4.08 mm² and is larger than 3.876 mm², which is the bonding area when six wires 44B having the second wire diameter are bonded to the emitter electrode 302 of the semiconductor element 3, and the surge energy capability is larger. Therefore, in a case where the size (dimension in Y direction×dimension in X direction) of the region ER in the semiconductor element 3 in which the emitter electrode 302 is exposed is 5.0×5.0 mm², the surge energy capability can be larger when 12 wires 44A having the first wire diameter are bonded to the emitter electrode 302 than when the wires 44B having the second wire diameter are bonded. In the graphs illustrated in FIGS. 7 to 9, the surge energy capability when 12 wires 44A having the first wire diameter are bonded to the emitter electrode 302 is about 10% larger than the surge energy capability when the six wires 44B having the second wire diameter are bonded. Specifically, as illustrated in FIG. 9, the maximum value of the surge energy capability when the wires 44B having the second wire diameter (400 μm) are bonded is about 6.0 kW, whereas the maximum value of the surge energy capability when the wires 44A having the first wire diameter (200 μm) are bonded is about 6.6 kW.

In a case where the size (dimension in Y direction×dimension in X direction) of the region ER in which the emitter electrode 302 is exposed is 5.0×5.0 mm², the number of the wires 44B having a wire diameter of 400 μm that can be bonded to the emitter electrode 302 can be six to seven at the maximum as described above. In the graph in FIG. 7, the number of the wires 44A having a wire diameter of 200 μm, which have a larger surge energy capability than in a case where the seven wires 44B having a wire diameter of 400 μm can be bonded, can be 11 or more. In a case where 11 wires 44A having a wire diameter of 200 μm are bonded to the emitter electrode 302 whose size (dimension in Y direction×dimension in X direction) of the region ER is 5.0×5.0 mm², as illustrated in FIG. 8, the number of bonding points is 44, and the surge energy capability is larger than that when seven wires 44B having a wire diameter of 400 μm are bonded (when the number of bonding points is 14). Assume that the wires 44A having a wire diameter of 200 μm are bonded to the emitter electrode 302 whose size (dimension in Y direction×dimension in X direction) of the region ER is 5.0×5.0 mm². When the number of wires is 12 or more, the surge energy capability can be further increased, and when the number of wires is 11, an increase in the time (takt time) required for wire bonding can be reduced.

In a case where the size (dimension in Y direction×dimension in X direction) of the region ER in which the emitter electrode 302 is exposed is 5.0×5.0 mm², as illustrated in FIG. 6, nine wires having a wire diameter of 300 μm can be bonded to the emitter electrode 302. In this example, each wire can be bonded to the emitter electrode 302 at three bonding points, the number of bonding points is 27, and the bonding area is 4.077 mm². An example of the surge energy capability when the nine wires having a wire diameter of 300 μm are bonded to the emitter electrode 302 of the semiconductor element 3 has a value indicated by the black rhombus in FIGS. 7 and 9, and is smaller than the surge energy capability when the 12 wires 44A having a wire diameter of 200 μm are bonded, but larger than the surge energy capability when the six wires 44B having a wire diameter of 400 μm are bonded.

In view of the above, in the semiconductor device 1 of the present embodiment, the surge energy capability of the semiconductor element 3 can be increased by selecting the number of wires such that the sum of the bonding areas when the wires 44A having a wire diameter of 200 μm are bonded to the emitter electrode 302 of the semiconductor element 3 is larger than the sum of the bonding areas when the wires having a larger wire diameter than the wires 44A having a wire diameter of 200 μm (for example, wires having a wire diameter of 400 μm or 300 μm) are bonded to the emitter electrode 302 and when the surge energy capability becomes the maximum value. In addition, the surge energy capability of the semiconductor element 3 can be increased by selecting the number of wires such that the sum of the bonding areas when the wires having a wire diameter of 300 μm are bonded to the emitter electrode 302 of the semiconductor element 3 is larger than the sum of the bonding areas when the wires having a larger wire diameter than the wires having a wire diameter of 300 μm (for example, wires 44B having a wire diameter of 400 μm) are bonded to the emitter electrode 302 and when the surge energy capability becomes the maximum value. That is, in the semiconductor device 1 of the present embodiment, the number of the plurality of wires connected to the emitter electrode 302 of the semiconductor element 3 is selected such that the wires include the wire having the first wire diameter, and that the sum of the bonding areas of the emitter electrode 302 is larger than the sum of the bonding areas when the wires having the second wire diameter which is larger than the first wire diameter are bonded to the emitter electrode and when the surge energy capability becomes the maximum value.

The relationship between the wire and the surge energy capability for each wire diameter described above with reference to FIGS. 6 and 7 to 9 is associated with the case where the size (dimension in Y direction×dimension in X direction) of the region ER in which the emitter electrode 302 is exposed is 5.0×5.0 mm². The above-described relationship can be rephrased by the relationship that does not depend on the size of the region ER in which the emitter electrode 302 is exposed by being converted into the number of bonding points per unit area and the bonding area per unit area of the emitter electrode 302.

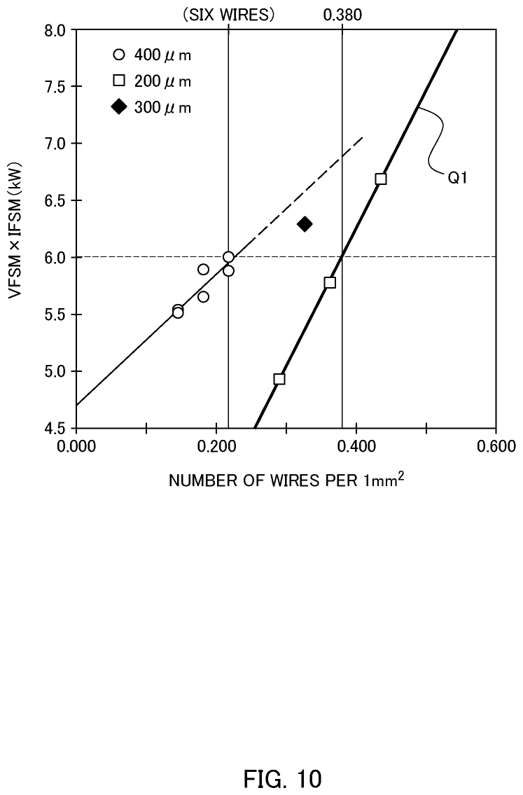

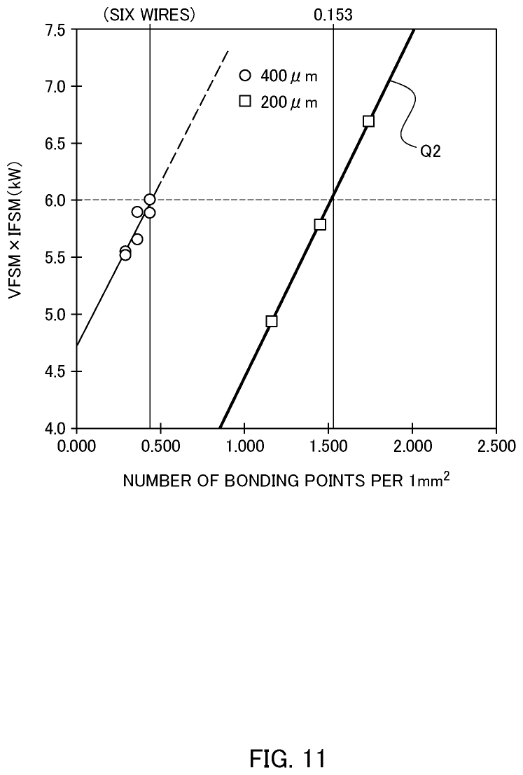

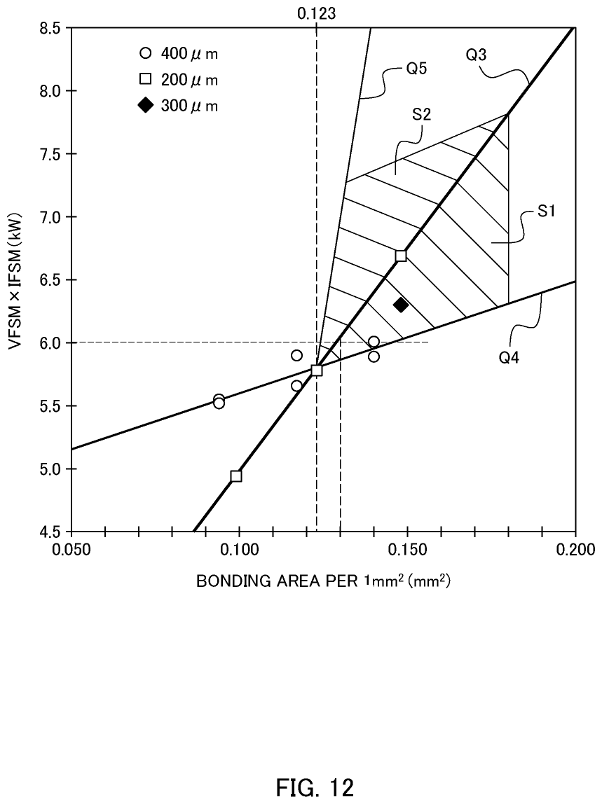

FIG. 10 is a graph illustrating a relationship between the number of wires per unit area and the surge energy capability for each wire diameter. FIG. 11 is a graph illustrating a relationship between the number of bonding points per unit area and the surge energy capability for each wire diameter. FIG. 12 is a graph illustrating a relationship between the bonding area per unit area and the surge energy capability for each wire diameter. The horizontal axis in the graphs in FIGS. 10, 11, and 12 can be a value obtained by dividing the value of the horizontal axis in the graphs in FIGS. 7, 8, and 9 by the size (5.0×5.0 mm²) of the region ER in which the emitter electrode 302 is exposed. That is, the unit area may be 1 mm². The “six wires” described on the upper side of each of the graphs in FIGS. 10 and 11 is intended to correspond to the value when six wires 44B having a wire diameter of 400 μm in the graphs in FIGS. 7 and 8 are used.

A straight line Q1 representing the relationship between the number of wires per unit area and the surge energy capability when the wires 44A having a wire diameter of 200 μm are used in the graph illustrated in FIG. 10 suggests that the surge energy capability when the number of wires per unit area is 0.380 or more is larger than the surge energy capability when six wires 44B having a wire diameter of 400 μm are used (surge energy capability is about 6.0 kW). In addition, a straight line Q2 representing the relationship between the number of bonding points per unit area and the surge energy capability when the wires 44A having a wire diameter of 200 μm are used in the graph illustrated in FIG. 11 suggests that the surge energy capability when the number of bonding points per unit area is 0.153 or more is larger than the surge energy capability when six wires 44B having a wire diameter of 400 μm are used (surge energy capability is about 6.0 kW).

In a case where the graph illustrated in FIG. 12 is compared with the graph in FIG. 10, the bonding area per 1 mm² of the electrode 302 of the semiconductor element 3 when 12 wires 44A having a wire diameter of 200 μm are bonded to the electrode 302 is larger than the bonding area per 1 mm² of the electrode 302 of the semiconductor element 3 when six wires 44B having a wire diameter of 400 μm are bonded to the electrode 302, in which case the surge energy capability is the maximum value (for example, about 6.0 kW).

Further, a straight line Q3 representing the relationship between the bonding area per unit area and the surge energy capability when the wires 44A having a wire diameter of 200 μm are used in the graph illustrated in FIG. 12 suggests that the surge energy capability when the bonding area per unit area (1 mm²) is greater than about 0.123 mm² is larger than the surge energy capability when the wires 44B having a wire diameter of 400 μm are used as indicated by a straight line Q4. In addition, as illustrated in FIG. 12, when the bonding area per unit area is about 0.150 mm², the surge energy capability in a case where the wire diameter is 200 μm, which is smaller, is larger than the surge energy capability in a case where the wire diameter is 300 μm. That is, in a case where wires having a wire diameter of 200 μm or more and less than 400 μm are bonded to the emitter electrode 302 of the semiconductor element 3, and where the wire diameter, the number of wires, and the number of bonding points are set such that the bonding area per 1 mm² of the electrode is 0.123 mm² or more and 0.18 mm² or less, the point indicating the relationship between the bonding area per 1 mm² of the electrode and the surge energy is in a region S1, and the surge energy capability can be larger than in a case where wires having a wire diameter of 400 μm or more are bonded to the emitter electrode 302 of the semiconductor element 3. Note that the region S1 in FIG. 12 may be a region in which the upper limit of the bonding area per 1 mm² of the electrode is a freely-selected value of less than 0.18 mm² or a freely-selected value of 0.18 mm² or more. In addition, the minimum value of the bonding area per 1 mm² of the electrode may be a value (for example, 0.13 mm²) derived when the surge energy capability is larger than the maximum value (about 6.0 kW) among the measured values of the surge energy capability when the wires having the wire diameter of 400 μm are used on the straight line Q3 in FIG. 12.

In addition, the graph in FIG. 12 suggests that the relationship between the bonding area per unit area and the surge energy when the wires having a wire diameter of less than 200 μm are used is as indicated by a straight line Q5. That is, when the bonding area per unit area is set to the same value of 0.123 mm² or more, the surge energy capability can be larger as a wire having a smaller wire diameter is used. When the wire diameter is reduced and the number of bonding points is increased, the time (takt time) required for connecting the emitter electrode 302 of the semiconductor element 3 and the wire is increased, and the energy required for bonding is increased, which may cause the manufacturing cost of the semiconductor device 1 to be increased. Therefore, the wire diameter and the bonding area per unit area are preferably determined, for example, within the ranges of the region S1 and a region S2 in FIG. 12 set on the basis of the surge energy capability required for the semiconductor device 1.

In the semiconductor device 1 applied to the power conversion device, since the switching operation of the switching element such as the IGBT element in the semiconductor element 3 is fast, a high surge current and surge voltage may be generated suddenly (for example, at the start of operation or the like). In a case where the surge current or the surge voltage suddenly generated exceeds an assumed value (rated value), the semiconductor element 3 is broken, and power cannot be supplied to a load (for example, a motor for a vehicle, an elevator, or the like) connected to the power conversion device. Therefore, the semiconductor device 1 is required to increase the surge energy capability of the semiconductor element 3 as much as possible.

In the semiconductor device described in Patent Literature 1, a portion between two bonding points in one wire is disposed along the surface of the emitter electrode of the semiconductor element 3 to reduce the wiring length (resistance value) of the portion between the bonding points, thereby increasing the surge current capability. However, since the semiconductor device of Patent Literature 1 does not determine the optimum wire diameter by considering the relationship between the bonding area and the surge current capability derived for each wire diameter, as described above with reference to FIGS. 7 to 9, the surge current capability may also decrease when the wire diameter is reduced. In addition, in the semiconductor device described in Patent Literature 2, a plurality of wires are bonded to an electrode of a semiconductor element in a non-uniform arrangement distribution, and it is difficult to increase the surge current capability by increasing the bonding area. On the other hand, in the semiconductor device 1 of the present embodiment, by considering the relationship between the bonding area and the surge energy capability derived for each wire diameter, it is possible to determine the optimum wire diameter at which the surge energy capability becomes high.

In the semiconductor device 1 of the present embodiment, the wire diameter of the wire bonded to the emitter electrode 302 of the semiconductor element 3 is not limited to 200 μm or 300 μm described above. The wire diameter may be, for example, 100 μm, 150 μm, 250 μm, or the like. The number of bonding points to the emitter electrode 302 of the semiconductor element 3 in each wire can be changed according to the combination of the size of the region ER in which the emitter electrode 302 is exposed and the wire diameter, and for example, the number of bonding points of the wire 44B having a wire diameter of 400 μm to the emitter electrode 302 may be three or more. In addition, the bonding points of the adjacent wires may be arranged in a direction different from the wire arrangement direction (X direction) illustrated in FIGS. 4A and 4B. For example, the bonding points of the adjacent wires may be shifted as much as a non-integral multiple (for example, ½) of the distance (for example, distance L1 in FIG. 4B) between the bonding points in one wire in the wire extending direction (Y direction). The plurality of wires bonded to the emitter electrode 302 of one semiconductor element 3 are not limited to those having the same wire diameter. For example, a wire having a wire diameter of 200 μm and a wire having a wire diameter of 400 μm may be included. In addition, in one semiconductor element 3, the wire diameter of the wire bonded to the emitter electrode 302 may be different from the wire diameter of the wire bonded to a third electrode (gate electrode).

In the semiconductor device 1 of the present embodiment, a semiconductor element in which a switching element such as an IGBT element is formed and a semiconductor element in which a diode element such as an FWD element is formed may be connected in parallel by a conductor pattern of a wiring board and a bonding wire. The switching element formed in the semiconductor element is not limited to the IGBT element, and may be, for example, a power Metal Oxide Semiconductor Field Effect Transistor (MOSFET) element or a Bipolar Junction Transistor (BJT) element. When the power MOSFET is used as the switching element, the collector and the emitter of the IGBT element described above are rephrased by the drain and the source, and the auxiliary emitter is rephrased by the auxiliary source. Furthermore, the diode element connected in antiparallel to the switching element may be, for example, a Schottky Barrier Diode (SBD) element, a Junction Barrier Schottky (JBS) diode element, a Merged PN Schottky (MPS) diode element, or a PN diode element. The semiconductor element is not limited to an element formed using silicon (Si), and may be an element using a wide bandgap semiconductor such as silicon carbide (SiC), gallium nitride (GaN), or diamond. The semiconductor device 1 may include a semiconductor element different from the switching element and the diode element.

Although the emitter electrode 302 of the switching element (IGBT element) of the semiconductor element 3 is connected to the plurality of wires in the above-described embodiment, the electrode of the semiconductor element 3 connected to the plurality of wires is not limited thereto. For example, the semiconductor element 3 may be disposed such that the surface on which the emitter electrode 302 and the gate electrode 303 are formed faces the wiring board 2. In this case, the electrode of the semiconductor element 3 connected to the plurality of wires may be the collector electrode of the IGBT element. When the semiconductor element in which the switching element is formed and the semiconductor element in which the diode element is formed are separate semiconductor elements, the plurality of wires described above may be connected to, for example, the electrode of the semiconductor element in which the diode element is formed. Further, when the switching element of the semiconductor element 3 is a power MOSFET element, the electrode 302 of the semiconductor element 3 connected to the wire 41 or 44 (see FIG. 1) may be the source electrode.

The semiconductor device 1 of the above-described embodiment is not limited to be used for a specific application, and can be applied to a high-output power conversion device such as an industrial power conversion device such as an inverter device that drives a motor of an elevator, an escalator, an air conditioning system of a building, or the like, or a power conversion device for a vehicle. The vehicle can be, for example, an electric vehicle that drives the wheels by a motor, or a hybrid vehicle using power of an internal combustion engine in addition to the motor. The vehicle is not limited to a four-wheeled vehicle, and may be a two-wheeled vehicle, a railway vehicle, or the like.

Feature points in the embodiment described above will be summarized below.

The semiconductor device according to the above-described embodiment includes a semiconductor element, and a plurality of wires bonded to an electrode exposed on a surface of the semiconductor element. The plurality of wires include a wire having a first wire diameter, and a sum of bonding areas of the electrode to the plurality of wires is 0.123 mm² or more per 1 mm² of the electrode of the semiconductor element.

In the semiconductor device according to the above-described embodiment, a distance between bonding points in the wire having the first wire diameter is 1.1 mm or less.

In the semiconductor device according to the above-described embodiment, the wire having the first wire diameter is bonded to the electrode at a plurality of bonding points, and a loop separated from the electrode is formed between the bonding points.

In the semiconductor device according to the above-described embodiment, a sum of bonding areas of the electrode and the plurality of wires is 0.13 mm² or more per 1 mm² of the electrode of the semiconductor element.

In the semiconductor device according to the above-described embodiment, the first wire diameter is 200 μm or 300 μm.

In the semiconductor device according to the above embodiment, the semiconductor element is made of a semiconductor substrate of any of silicon, silicon carbide, and gallium nitride, and the electrode of the semiconductor element is an emitter electrode of an Insulated Gate Bipolar Transistor (IGBT) element, or a source electrode of a Metal Oxide Semiconductor Field Effect Transistor (MOSFET) element.

In the semiconductor device according to the above-described embodiment, per 1 mm² of the electrode, a first sum, which is a sum of bonding areas between the electrode and the plurality of wires having the first wire diameter, is larger than a second sum, which is a sum of bonding areas between the electrode and a plurality of wires having a second wire diameter larger than the first wire diameter when a surge energy capability is a maximum value.

In the semiconductor device according to the above embodiment, in a case where, per 1 mm² of the electrode, the first sum, which is a sum of bonding areas between the electrode and the plurality of wires having the first wire diameter, and the second sum, which is a sum of bonding areas between the electrode and the plurality of wires having the second wire diameter larger than the first wire diameter, are equal, a semiconductor element having the electrode bonded using the plurality of wires having the first wire diameter has a larger surge energy capability than a semiconductor element having the electrode bonded using the plurality of wires having the second wire diameter.

Note that the present invention is not limited to the above-described embodiments, and various changes, substitutions, and modifications may be made without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

### INDUSTRIAL APPLICABILITY

As described above, the present invention has an effect that it is possible to increase the surge energy capability of the semiconductor element in the semiconductor device, and it is possible to prevent the semiconductor element from being destroyed by a high current that is suddenly generated, and is particularly useful by being applied to an industrial or vehicular semiconductor device used as a power conversion device.

The present application is based on Japanese Patent Application No. 2024-091877 filed on Jun. 6, 2024. All the contents of this application are included herein.

1. A semiconductor device comprising:
a semiconductor element having an electrode exposed on a surface thereof; and
a plurality of wires bonded to the electrode, thereby forming a plurality of bonding areas thereof,
wherein each of the plurality of wires is of a first wire diameter, and
wherein a ratio of a total area of the plurality of bonding areas to an area of the electrode is at least 0.123.

2. The semiconductor device according to claim 1, wherein each of the plurality of wires is bonded to the electrode at a plurality of bonding points, a distance between each adjacent two of the plurality of bonding points being 1.1 mm or less.

3. The semiconductor device according to claim 2, wherein said each wire has a loop separated from the electrode formed between each adjacent two of the plurality of bonding points.

4. The semiconductor device according to claim 3, wherein a ratio of the total area of the plurality of bonding areas to the area of the electrode of is at least 0.13.

5. The semiconductor device according to claim 4, wherein the first wire diameter is 200 μm or 300 μm.

6. The semiconductor device according to claim 5, wherein the semiconductor element is made of a semiconductor substrate of silicon, silicon carbide, or gallium nitride, and
wherein the semiconductor element is
an Insulated Gate Bipolar Transistor (IGBT) element, with the electrode being an emitter electrode thereof, or
a Metal Oxide Semiconductor Field Effect Transistor (MOSFET) element, with the electrode being a source electrode thereof.

7. The semiconductor device according to claim 6, wherein, per 1 mm² of the electrode, a first sum, which is a sum of bonding areas between the electrode and the plurality of wires having the first wire diameter, is larger than a second sum, which is a sum of bonding areas between the electrode and a plurality of wires having a second wire diameter larger than the first wire diameter when a surge energy capability is a maximum value.

8. The semiconductor device according to claim 7, wherein, in a case where, per 1 mm² of the electrode, the first sum, which is a sum of bonding areas between the electrode and the plurality of wires having the first wire diameter, and the second sum, which is a sum of bonding areas between the electrode and the plurality of wires having the second wire diameter larger than the first wire diameter, are equal, a semiconductor element having the electrode bonded using the plurality of wires having the first wire diameter has a larger surge energy capability than a semiconductor element having the electrode bonded using the plurality of wires having the second wire diameter.
